(19) United States
(12) Patent Application Publication
(10) Pub. No.: US 2025/0277297 A1
(43) Pub. Date: Sep. 4, 2025

(54) MASK ASSEMBLY, METHOD FOR MANUFACTURING MASK ASSEMBLY, AND DISPLAY DEVICE

(71) Applicant: LG Display Co., Ltd., Seoul (KR)

(72) Inventors: Minwoo LEE, Paju-si (KR); Hyesook KIM, Paju-si (KR); Hyunsuk LEE, Paju-si (KR); SangWook LEE, Paju-si (KR)

(73) Assignee: LG Display Co., Ltd., Seoul (KR)

(21) Appl. No.: 19/058,364

(22) Filed: Feb. 20, 2025

(30) Foreign Application Priority Data
Feb. 29, 2024 (KR) 10-2024-0030159

(51) Int. Cl. C23C 14/04; H10K 59/122; H10K 59/131; H10K 59/80; H10K 71/16

(52) U.S. Cl. CPC C23C 14/042; H10K 59/122; H10K 59/131; H10K 59/873; H10K 71/166

(57) ABSTRACT

Aspects of the subject technology provide a mask assembly that allows a display device to have a narrow bezel and a highly reliable structure, where the mask assembly may include a mask frame and a mask stick coupled to the mask frame and including a first mask stick spaced apart in a first direction and extending in a second direction crossing the first direction and a second mask stick spaced apart in the second direction and extending in the first direction. Two opposite end surfaces of the second mask stick may be respectively coupled to corresponding side surfaces of the first mask sticks that may be spaced apart from each other. A method for manufacturing the mask assembly, and a display device are also disclosed.

### CROSS-REFERENCE TO RELATED APPLICATION

This application claims the benefit of and priority to Korean Patent Application No. 10-2024-0030159, filed on Feb. 29, 2024, the entirety of which is incorporated herein by reference for all purposes as if fully set forth herein.

### BACKGROUND

### 1. Technical Field

Embodiments of the present disclosure relate to a mask assembly, a method of manufacturing the mask assembly, and a display device.

### 2. Description of Related Art

The advent of information era has led to a rapid advance in displays for visually expressing electrical information signals and development of various display devices with excellent performance in thinness, light weight, and low power consumption.

Some examples of such display devices include liquid crystal display (LCD) devices, plasma display panel (PDP) devices, field emission display (FED) devices, and organic light emitting display (OLED) devices.

Recently, studies have been actively conducted to provide a larger display area in display devices. In other words, vigorous research efforts are being made to narrow bezel technology for providing broader and larger images to users by increasing the image-output portion while minimizing the edge portion where no image is output.

The description of the related art should not be assumed to be prior art merely because it is mentioned in or associated with this section. The description of the related art includes information that describes one or more aspects of the subject technology, and the description in this section does not limit the invention.

### SUMMARY

One or more example embodiments of the present disclosure may provide a mask assembly which allows a display device to have a narrow bezel and a highly reliable structure, a method for manufacturing the mask assembly, and a display device.

One or more example embodiments of the present disclosure may provide a mask assembly having a structure advantageous in implementing a narrow bezel in a display device, a method for manufacturing the mask assembly, and a display device.

One or more example embodiments of the present disclosure may provide a mask assembly having a structure capable of preventing penetration of external materials, such as moisture or oxygen, in a display device, a method for manufacturing the mask assembly, and a display device.

One or more example embodiments of the present disclosure may provide a mask assembly having a structure capable of preventing generation of particles due to plasma, a method for manufacturing the mask assembly, and a display device.

One or more example embodiments of the present disclosure may provide a mask assembly having a structure capable of blocking diffusion of external materials introduced into a display device and/or to a display area, a method for manufacturing the mask assembly, and a display device.

One or more example embodiments of the present disclosure may provide a mask assembly comprising a mask frame and a mask stick coupled to the mask frame and including a plurality of first mask sticks spaced apart in a first direction and extending in a second direction crossing the first direction and a plurality of second mask sticks spaced apart in the second direction and extending in the first direction, wherein two opposite end surfaces of the second mask stick may be respectively coupled to corresponding side surfaces of the first mask sticks that may be spaced apart from each other.

The first mask stick or the second mask stick may include a mask stick body and a coating layer coated on the mask stick body.

One or more example embodiments of the present disclosure may provide a method for manufacturing a mask assembly comprising providing a mask frame, coupling the mask frame to a first mask stick, where a plurality of the first mask sticks may be spaced apart in a first direction, and coupling the first mask stick to a second mask stick, where a plurality of the second mask sticks may be spaced apart in a second direction crossing the first direction, wherein two opposite end surfaces of the second mask stick may be respectively welded to corresponding side surfaces of the first mask sticks that may be spaced apart from each other.

One or more example embodiments of the present disclosure may provide a display device comprising a substrate, a display area where a plurality of subpixels are disposed, a non-display area outside the display area, a circuit unit disposed on the substrate and disposed in the non-display area, an overcoat layer disposed on the circuit unit, a bank extending from the display area to the non-display area and disposed on the overcoat layer, an intermediate layer extending from the display area to the non-display area and disposed on the bank, a common electrode extending from the display area to the non-display area and disposed on the intermediate layer, and an inorganic encapsulation layer extending from the display area to the non-display area and disposed to cover an upper portion and a side surface of the common electrode.

According to one or more example embodiments of the present disclosure, there may be provided a mask assembly which allows a display device to have a narrow bezel and a highly reliable structure, a method for manufacturing the mask assembly, and a display device.

According to one or more example embodiments of the present disclosure, there may be provided a mask assembly having a structure advantageous in implementing a narrow bezel in a display device, a method for manufacturing the mask assembly, and a display device.

According to one or more example embodiments of the present disclosure, there may be provided a mask assembly having a structure capable of preventing penetration of external materials, such as moisture or oxygen, in a display device, a method for manufacturing the mask assembly, and a display device.

According to one or more example embodiments of the present disclosure, there may be provided a mask assembly having a structure capable of preventing generation of particles due to plasma, a method for manufacturing the mask assembly, and a display device.

According to one or more example embodiments of the present disclosure, there may be provided a mask assembly having a structure capable of blocking diffusion of external materials introduced into a display device and/or to a display area, a method for manufacturing the mask assembly, and a display device.

According to one or more example embodiments of the present disclosure, there may be provided a mask assembly which allows for a lightweight display device by having an extremely narrow bezel structure, a method for manufacturing the mask assembly, and a display device.

Other apparatuses, assemblies, display devices, methods, features and advantages will be, or will become, apparent to one with skill in the art upon examination of the drawings and detailed description herein. It is intended that all such apparatuses, assemblies, display devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a view illustrating a system configuration of a display device according to one or more example embodiments of the present disclosure;

FIG. 2 illustrates a display panel according to one or more example embodiments of the present disclosure;

FIG. 3 is an example view illustrating a system implementation of a display device according to one or more example embodiments of the present disclosure;

FIG. 4 is an example cross-sectional view illustrating a display panel according to one or more example embodiments of the present disclosure;

FIG. 5 depicts example diagrams illustrating a shadow phenomenon of an inorganic encapsulation layer of a display panel according to one or more example embodiments of the present disclosure;

FIG. 6 is an example diagram illustrating an image abnormality of a display panel according to one or more example embodiments of the present disclosure;

FIGS. 7 and 8 are example diagrams illustrating a shadow phenomenon of an inorganic encapsulation layer according to the distance between a substrate and a mask stick in a display panel according to one or more example embodiments of the present disclosure;

FIG. 9 is an example plan view illustrating a mask assembly according to one or more example embodiments of the present disclosure;

FIG. 10 is an example cross-sectional view taken along line A-B of FIG. 9;

FIG. 11 is another example plan view illustrating a mask assembly according to one or more example embodiments of the present disclosure;

FIG. 12 is an example cross-sectional view taken along line C-D of FIG. 11;

FIG. 13 is another example plan view illustrating a mask assembly according to one or more example embodiments of the present disclosure;

FIG. 14 is an example cross-sectional view taken along line E-F of FIG. 13;

FIG. 15 is an example cross-sectional view illustrating a mask stick having a coating layer according to one or more example embodiments of the present disclosure;

FIG. 16 is another example cross-sectional view illustrating a mask stick having a coating layer according to one or more example embodiments of the present disclosure;

FIG. 17 is an example process flowchart illustrating a method for manufacturing a mask assembly according to one or more example embodiments of the present disclosure;

FIG. 18 is an example cross-sectional view illustrating a display panel according to one or more example embodiments of the present disclosure; and

FIG. 19 is another example cross-sectional view illustrating a display panel according to one or more example embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, at least a portion (or a part) of an element can represent (i) a portion (or a part) of the element, (ii) one or more portions (or parts) of the element, or (iii) the element, or the entirety of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

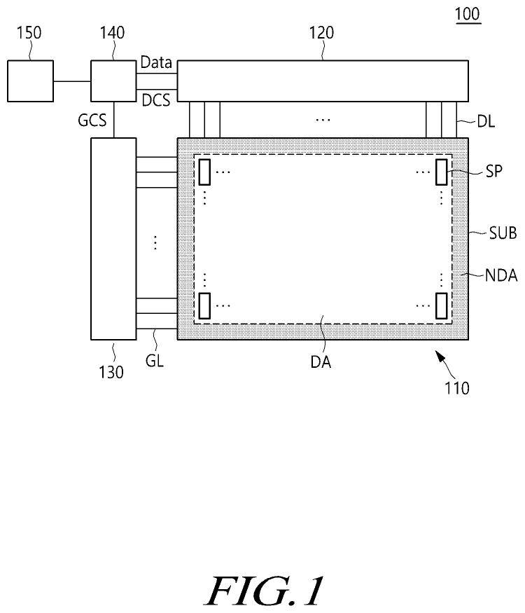

FIG. 1 is a view illustrating a system configuration of a display device 100 according to one or more example embodiments of the present disclosure.

Referring to FIG. 1, according to one or more example embodiments of the present disclosure, a display device 100 may include a display panel 110 and driving circuits for driving the display panel 110.

The driving circuits may include a data driving circuit 120 and a gate driving circuit 130. The display device 100 may further include a controller 140 controlling the data driving circuit 120 and the gate driving circuit 130.

The display panel 110 may include a substrate SUB and signal lines, such as a plurality of data lines DL and a plurality of gate lines GL disposed on the substrate SUB. The display panel 110 may include a plurality of subpixels SP connected to the plurality of data lines DL and the plurality of gate lines GL.

The display panel 110 may include a display area DA in which images are displayed and a non-display area NDA in which no image is displayed. In the display panel 110, a plurality of subpixels SP for displaying images may be disposed in the display area DA, and the data driving circuits 120, the gate driving circuit 130, and the controller 140 may be electrically connected or disposed in the non-display area NDA. Further, pad units for connection of integrated circuits or a printed circuit may be disposed in the non-display area NA.

The data driving circuit 120 is a circuit for driving the plurality of data lines DL, and may supply data signals to the plurality of data lines DL.

The gate driving circuit 130 is a circuit for driving the plurality of gate lines GL, and may supply gate signals to the plurality of gate lines GL.

The controller 140 may supply a data control signal DCS to the data driving circuit 120 to control the operation timing of the data driving circuit 120 and may supply a gate control signal GCS to the gate driving circuit 130 to control the operation timing of the gate driving circuit 130.

The controller 140 may start scanning according to a timing implemented in each frame, convert input image data input from the outside into image data Data suited for the data signal format used in the data driving circuit 120, supply the image data Data to the data driving circuit 120, and control data driving at an appropriate time suited for scanning.

The controller 140 receives, from the outside (e.g., a host system 150), various timing signals including a vertical synchronization signal VSYNC, a horizontal synchronization signal HSYNC, an input data enable signal DE, and a clock signal, along with the input image data.

To control the data driving circuit 120 and the gate driving circuit 130, the controller 140 receives timing signals, such as the vertical synchronization signal VSYNC, horizontal synchronization signal HSYNC, input data enable signal DE, and clock signal CLK, generates various control signals DCS and GCS, and outputs the control signals to the data driving circuit 120 and the gate driving circuit 130.

As an example, to control the gate driving circuit 130, the controller 140 outputs various gate control signals GCS including a gate start pulse GSP, a gate shift clock GSC, and a gate output enable signal (Gate Output Enable, GOE).

To control the data driving circuit 120, the controller 140 outputs various data control signals DCS including, e.g., a source start pulse SSP, a source sampling clock SSC, and a source output enable signal (Source Output Enable, SOE).

The controller 140 may be implemented as a separate component from the data driving circuit 120, or the controller 140, along with the data driving circuit 120, may be implemented as an integrated circuit.

The data driving circuit 120 receives the image data Data from the controller 140 and supply data voltages to the plurality of data lines DL, thereby driving the plurality of data lines DL. The data driving circuit 120 is also referred to as a ‘source driving circuit.’

The data driving circuit 120 may include one or more source driver integrated circuit (SDICs).

Each source driver integrated circuit (SDIC) may include a shift register, a latch circuit, a digital-to-analog converter (DAC), and an output buffer. In some cases, each source driver integrated circuit (SDIC) may further include an analog-digital converter ADC.

For example, each source driver integrated circuit (SDIC) may be connected with the display panel 110 by a tape automated bonding (TAB) type or connected to a bonding pad of the display panel 110 by a chip on glass (COG) or chip on panel (COP) type or may be implemented by a chip on film (COF) type and connected with the display panel 110.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

Meanwhile, at least one of the data driving circuit 120 and the gate driving circuit 130 may be disposed in the display area DA.

For example, the gate driving circuit 130 may be disposed in the display area DA. In this case, the gate driving circuit 130 may be disposed throughout the display area DA or may be disposed only in a portion of the display area DA. The gate driving circuit 130 may be disposed not to overlap the subpixels SP or to overlap all or some of the subpixels SP.

For example, the data driving circuit 120 may be disposed in the display area DA. In this case, the data driving circuit 120 may be disposed throughout the display area DA or may be disposed only in a portion of the display area DA. The data driving circuit 120 may be disposed not to overlap the subpixels SP or to overlap all or some of the subpixels SP.

When a specific gate line GL is selected by the gate driving circuit 130, the data driving circuit 120 may convert the image data Data received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the driving scheme or the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point to point interface (EPI), and a serial peripheral interface (SPI).

The controller 140 may include a storage medium, such as one or more registers.

The display device 100 according to one or more example embodiments of the present disclosure may be a display device in which the display panel 110 is incapable of self-emission. For example, the display device 100 according to one or more example embodiments of the present disclosure may be a liquid crystal display device including a backlight unit.

Unlike this, the display device 100 according to one or more example embodiments of the present disclosure may be a self-emission display device in which the display panel 110 may emit light by itself. For example, the display device 100 according to one or more example embodiments of the present disclosure may be one of an organic light emitting diode (OLED) display device, a quantum dot display, a micro LED display device, or the like.

When the display device 100 according to one or more example embodiments of the present disclosure is an organic light emitting diode display device, each subpixel SP may include an organic light emitting diode OLED that emits light by itself as the light emitting element. When the display device 100 according to one or more example embodiments of the present disclosure is a quantum dot display device, each subpixel SP may include a light emitting element formed of quantum dots that are semiconductor crystals that emit light by themselves. When the display device 100 according to one or more example embodiments of the present disclosure is a micro light emitting diode display device, each subpixel SP may include a micro light emitting diode that emits light by itself and is formed based on an inorganic material, as the light emitting element.

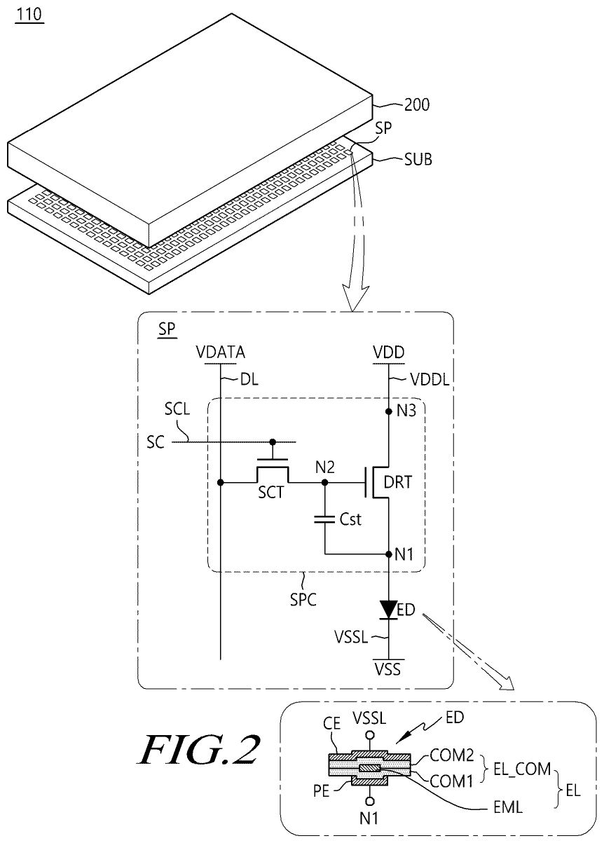

FIG. 2 illustrates a display panel 110 according to one or more example embodiments of the present disclosure.

Referring to FIG. 2, the display panel 110 may include a substrate SUB where a plurality of subpixels SP are disposed and an encapsulation layer 200 on the substrate SUB. Here, the encapsulation layer 200 may also be referred to as an encapsulation substrate or an encapsulation portion.

Referring to FIG. 2, when the display device 100 according to one or more example embodiments of the present disclosure is a self-luminous display device, each of the plurality of subpixels SP disposed on the substrate SUB may include a light emitting element ED and a subpixel circuit SPC for driving the light emitting element ED.

Referring to FIG. 2, the subpixel circuit SPC may include a plurality of pixel driving transistors and at least one capacitor for driving the light emitting element ED. In the disclosure, the subpixel circuit SPC may drive the light emitting element ED by supplying a driving current to the light emitting element ED at a predetermined timing. The light emitting element ED may be driven by a driving current to emit light.

The plurality of pixel driving transistors may include a driving transistor DRT for driving the light emitting element ED and a scan transistor SCT that is turned on or off according to the scan signal SC.

The driving transistor DRT may supply a driving current to the light emitting element ED.

The scan transistor SCT may be configured to control the electrical state of a corresponding node (the second node N2) in the subpixel circuit SPC or to control the state or operation of the driving transistor DRT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common driving voltage including the first common driving voltage VDD and the second common driving voltage VSS may be applied to the subpixel SP.

The light emitting element ED may include a pixel electrode PE, an intermediate layer EL, and a common electrode CE. An intermediate layer EL may be disposed between the pixel electrode PE and the common electrode CE.

When the light emitting element ED is an organic light emitting element, the intermediate layer EL may include a light emitting layer EML and a common intermediate layer EL_COM. The common intermediate layer EL_COM may include a first common intermediate layer COM1 and a second common intermediate layer COM2. The first common intermediate layer COM1 may be disposed between the pixel electrode PE and the light emitting layer EML and may include at least one layer (e.g., an organic film). The second common intermediate layer COM2 may be disposed between the light emitting layer EML and the common electrode CE and may include at least one layer (e.g., an organic film).

As an example, the light emitting layer EML may be disposed in each of the plurality of subpixels SP, or as another example, may be commonly disposed in the plurality of subpixels SP. The common intermediate layer EL_COM may be commonly disposed over the plurality of subpixels SP.

The light emitting layer EML may be disposed for each light emitting area, and the common intermediate layer EL_COM may be commonly disposed over the plurality of light emitting areas and the non-light emitting area.

The pixel electrode PE may be an electrode disposed in each subpixel SP, and the common electrode CE may be an electrode commonly disposed in the plurality of subpixels SP.

For example, the pixel electrode PE may be an anode and the common electrode CE may be a cathode. As another example, the pixel electrode PE may be a cathode and the common electrode CE may be an anode. Hereinafter, an example in which the pixel electrode PE is an anode and the common electrode CE is a cathode is described.

For example, the first common intermediate layer COM1 of the common intermediate layer EL_COM may include a hole injection layer HIL and a hole transport layer HTL. The second common intermediate layer COM2 of the common intermediate layer EL_COM may include an electron transport layer ETL and an electron injection layer EIL.

The hole injection layer may inject holes from the pixel electrode PE to the hole transport layer, the hole transport layer may transport the holes to the light emitting layer EML, the electron injection layer may inject electrons from the common electrode CE to the electron transport layer, and the electron transport layer may transport electrons to the light emitting layer EML.

For example, the common electrode CE may be electrically connected to the second common driving voltage line VSSL. The second common driving voltage VSS, which is one type of common driving voltage, may be applied to the common electrode CE through the second common driving voltage line VSSL. The pixel electrode PE may be electrically connected directly or indirectly (through another transistor) to the first node N1 of the driving transistor DRT of each subpixel SP. In the disclosure, “the second common driving voltage VSS” may also be referred to as a “base voltage VSS,” and “the second common driving voltage line VSSL” may also be referred to as a “base voltage line VSSL.”

Each light emitting element ED may include an overlapping portion of the pixel electrode PE, the light emitting layer EML in the intermediate layer EL, and the common electrode CE. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), or a quantum dot light emitting element. For example, when the light emitting element ED is an organic light emitting diode (OLED), the intermediate layer EL in the light emitting element ED may include an organic film including an organic material.

The driving transistor DRT may be a driving transistor for supplying a driving current to the light emitting element ED. The driving transistor DRT may be connected between the first common driving voltage line VDDL and the light emitting element ED.

The driving transistor DRT may include a first node N1, a second node N2, and a third node N3. The first node N1 may be electrically connected to the light emitting element ED, the second node N2 may receive a data signal VDATA, and the third node N3 may receive a first common driving voltage VDD from the first common driving voltage line VDDL.

In the driving transistor DRT, the second node N2 may be a gate node, the first node N1 may be a source node or a drain node, and the third node N3 may be a drain node or a source node. Hereinafter, for convenience of description, in the driving transistor DRT, the second node N2 may be a gate node, the first node N1 may be a source node, and the third node N3 may be a drain node.

The scan transistor SCT included in the subpixel circuit SPC illustrated in FIG. 2 may be a switching transistor for transferring the data signal VDATA, which is an image signal, to the second node N2, which is the gate node of the driving transistor DRT.

The scan transistor SCT may be controlled to be turned on and off by the scan signal SC, which is a gate signal applied through the scan signal line SCL, which is a type of the gate line GL, to control electrical connection between the second node N2 of the driving transistor DRT and the data line DL. The drain electrode or the source electrode of the scan transistor SCT may be electrically connected to the data line DL, the source electrode or the drain electrode of the scan transistor SCT may be electrically connected to the second node N2 of the driving transistor DRT, and the gate electrode of the scan transistor SCT may be electrically connected to the scan signal line SCL.

The storage capacitor Cst may be electrically connected between the first node N1 and the second node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

The capacitor Cst may be an external capacitor intentionally designed to be outside the driving transistor DRT, but not a parasite capacitor (e.g., Cgs or Cgd) which is an internal capacitor that may be present between the first node N1 and the second node N2 of the driving transistor DRT.

Each of the driving transistor DRT and the scan transistor SCT may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. Accordingly, the area of the light emitting area may increase and the aperture ratio may increase.

When the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

Depending on the structure of the subpixel circuit SPC, the type and number of gate lines or the gate signals supplied to the subpixel SP may vary. Further, the type and the number of common driving voltages supplied to the subpixel SP may vary depending on the structure of the subpixel circuit SPC.

Since the circuit elements (especially the light emitting element ED implemented as the organic light emitting diode (OLED) including an organic material) in each subpixel SP are vulnerable to external moisture or oxygen, the encapsulation layer 200 for preventing external moisture or oxygen from penetrating into the circuit elements (especially the light emitting element ED) may be disposed on the display panel 110. The encapsulation layer 200 may be configured in various forms so that the light emitting elements ED do not contact moisture or oxygen.

Meanwhile, the display device 100 according to one or more example embodiments of the present disclosure may have an extremely narrow bezel structure in which the non-display area NDA of the display panel 110 is very small.

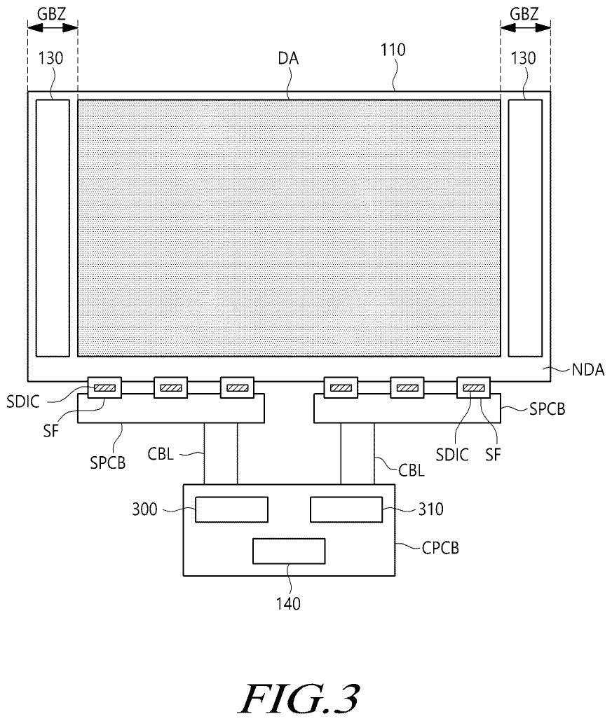

FIG. 3 is an example view illustrating a system implementation of a display device 100 according to one or more example embodiments of the present disclosure.

Referring to FIG. 3, a display panel 110 may include a display area DA in which an image is displayed and a non-display area NDA in which an image is not displayed.

Referring to FIG. 3, when the data driving circuit 120 includes one or more source driver integrated circuits SDICs and is implemented in a chip-on-film (COF) type, each source driver integrated circuit SDIC may be mounted on a circuit film SF connected to the non-display area NDA of the display panel 110.

Referring to FIG. 3, a gate driving circuit 130 may be implemented in a gate in panel (GIP) type. In this case, the gate driving circuit 130 may be formed in the non-display area NDA of the display panel 110. Unlike FIG. 3, the gate driving circuit 130 may be implemented in a chip on film (COF) type.

The display device 100 may include at least one source printed circuit board SPCB for circuit connection between one or more source driver integrated circuits SDIC and other devices and a control printed circuit board CPCB for mounting control components and various electric devices.

The source driver integrated circuit SDIC-packed film SF may be connected to at least one source printed circuit board SPCB. In other words, one side of the source driver integrated circuit SDIC-packed film SF may be electrically connected with the display panel 110, and the opposite side thereof may be electrically connected with the source printed circuit board SPCB.

A controller 140 and a power management integrated circuit (PMIC) 310 may be mounted on the control printed circuit board CPCB. The controller 140 may perform overall control functions related to driving of the display panel 110, and may control operations of the data driving circuit 120 and the gate driving circuit 130. The power management integrated circuit 310 may supply various voltages or currents to the data driving circuit 120 and the gate driving circuit 130 or may control various voltages or currents to be supplied thereto.

At least one source printed circuit board SPCB and the control printed circuit board CPCB may be circuit-connected through at least one connection cable CBL. Here, the connection cable CBL may be, e.g., a flexible printed circuit (FPC) or a flexible flat cable (FFC).

At least one source printed circuit board SPCB and control printed circuit board CPCB may be integrated into one printed circuit board.

The display device 100 according to one or more example embodiments of the present disclosure may further include a level shifter 300 for adjusting a voltage level. For example, the level shifter 300 may be disposed on a control printed circuit board CPCB or a source printed circuit board SPCB.

In the display device 100 according to one or more example embodiments of the present disclosure, the level shifter 300 may supply signals necessary for gate driving to the gate driving circuit 130. For example, the level shifter 300 may supply a plurality of clock signals (gate clock signals) to the gate driving circuit 130. Accordingly, the gate driving circuit 130 may generate a plurality of gate signals based on the plurality of gate clock signals input from the level shifter 300 and output them to the plurality of gate lines GL. The plurality of gate lines GL may transfer the plurality of gate signals to the subpixels SP disposed in the display area DA of the substrate SUB.

Referring to FIG. 3, the non-display area NDA of the display panel 110 may include a gate bezel area GBZ in which the gate driving circuit 130 and related lines are disposed.

Referring to FIG. 3, not only the gate driving circuit 130 of the GIP type is disposed in the gate bezel area GBZ, but various lines necessary for the operation of the gate driving circuit 130 should be disposed. Here, various lines necessary for the operation of the gate driving circuit 130 may include a plurality of gate clock lines, at least one high-level gate voltage line, at least one low-level gate voltage line, and the like.

Hereinafter, a structure of the gate bezel area GBZ of the display panel 110 according to one or more example embodiments of the present disclosure is described in more detail.

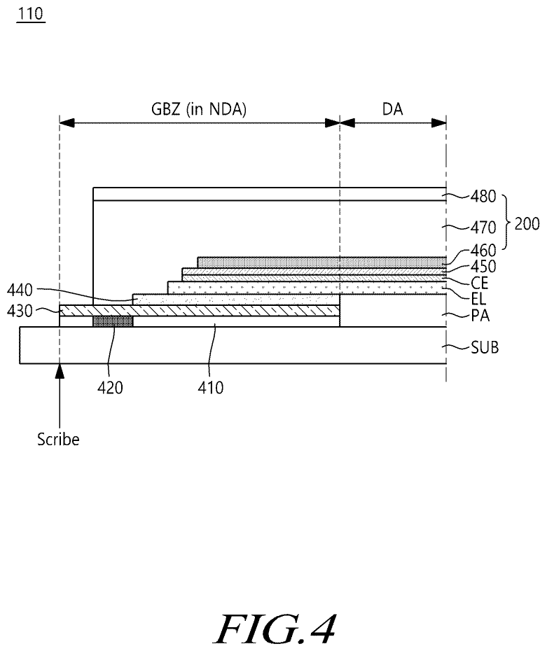

FIG. 4 is a cross-sectional view of a display panel 110 according to one or more example embodiments of the present disclosure. However, the cross-sectional view of FIG. 4 shows a state before a scribe process is performed in the manufacturing process of the display panel 110.

Referring to FIG. 4, the display panel 110 according to one or more example embodiments of the present disclosure may include a substrate SUB, a circuit unit 410, an overcoat layer 430, a bank 440, an intermediate layer EL, a common electrode CE, an inorganic encapsulation layer 460, and the like.

The circuit unit 410 may include a gate driving circuit 130 of a GIP type.

The circuit unit 410 may be disposed on the substrate SUB and may be disposed in the gate bezel area GBZ in the non-display area NDA.

The overcoat layer 430 may be disposed on the circuit unit 410.

The bank 440 may be disposed on the overcoat layer 430.

The intermediate layer EL may extend from the display area DA to the non-display area NDA and may be disposed on the bank 440. The intermediate layer EL may overlap at least a portion of the circuit unit 410 disposed in the gate bezel area GBZ in the non-display area NDA.

The common electrode CE may extend from the display area DA to the non-display area NDA and may be disposed on the intermediate layer EL. The common electrode CE may overlap at least a portion of the circuit unit 410 disposed in the gate bezel area GBZ in the non-display area NDA.

The inorganic encapsulation layer 460 may be an inorganic layer included in the encapsulation layer 200, and may extend from the display area DA to the non-display area NDA to be disposed on the common electrode CE. The inorganic encapsulation layer 460 may overlap at least a portion of the circuit unit 410 disposed in the gate bezel area GBZ in the non-display area NDA. For example, the inorganic encapsulation layer 460 may include one or more of silicon nitride (SiNₓ), silicon oxide (SiOₓ), silicon nitride (SiON), and the like.

Referring to FIG. 4, the display panel 110 according to one or more example embodiments of the present disclosure may further include an adhesive layer 470 and a metal encapsulation layer 480 on the adhesive layer 470. The encapsulation layer 200 may include an inorganic encapsulation layer 460, an adhesive layer 470, and a metal encapsulation layer 480.

Referring to FIG. 4, the display panel 110 according to one or more example embodiments of the present disclosure may further include a ground line 420 disposed further outside the circuit unit 410.

Referring to FIG. 4, the display panel 110 according to one or more example embodiments of the present disclosure may further include a capping layer 450 on the common electrode CE. The capping layer 450 may be regarded as a layer included in the encapsulation layer 200.

Referring to FIG. 4, in the display panel 110 according to one or more example embodiments of the present disclosure, the pixel area PA in the display area DA is an area in which a plurality of subpixels SP are formed, and a plurality of signal lines, a plurality of transistors, a plurality of capacitors, a plurality of pixel electrodes, and the like may be disposed. Further, various metal layers and various insulation layers for disposing a plurality of signal lines, a plurality of transistors, a plurality of capacitors, a plurality of pixel electrodes, and the like may be disposed in the pixel area PA.

For example, in the pixel area PA, a plurality of transistors including a driving transistor DRT, a scan transistor SCT, and the like, and a plurality of storage capacitors Cst may be disposed. Further, a plurality of signal lines including a plurality of data lines DL, a plurality of gate lines GL, a plurality of first common driving voltage lines VDDL, and the like may be disposed in the pixel area PA.

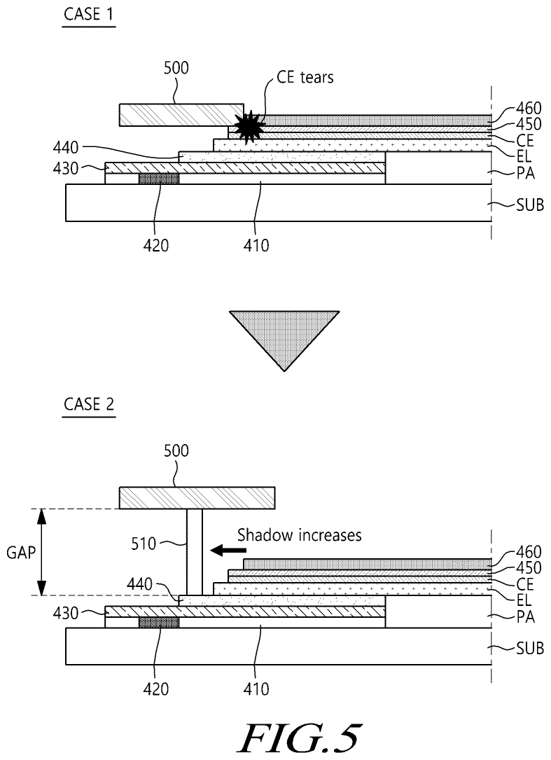

FIG. 5 depicts example diagrams illustrating a shadow phenomenon of an inorganic encapsulation layer 460 of a display panel 110 according to one or more example embodiments of the present disclosure.

Referring to FIG. 5, when the inorganic encapsulation layer 460 is deposited during the manufacturing process of the display panel 110, if the gap between the deposition mask stick 500 and the substrate SUB is too close as in case 1, the common electrode CE may be torn during or after the deposition process.

In order to prevent tearing of the common electrode CE, as in case 2, the deposition process of the inorganic encapsulation layer 460 is performed, with a protrusion 510 formed on the back surface of the deposition mask stick 500 to widen the gap GAP between the deposition mask stick 500 and the substrate SUB. The protrusion 510 may be referred to as floating metal embossing (FME).

The minimum gap GAP between the deposition mask stick 500 and the substrate SUB for preventing tearing of the common electrode CE may be larger than or equal to a threshold determined for each type of the display panel 110.

Referring to FIG. 5, when the deposition process of the inorganic encapsulation layer 460 is performed as in case 2, the inorganic encapsulation layer 460 may be deposited to extend further outward than a desired point due to the widened gap GAP between the deposition mask stick 500 and the substrate SUB.

In example embodiments of the present disclosure, a phenomenon in which the inorganic encapsulation layer 460 extends further outward than a desired point is referred to as a “shadow phenomenon of the inorganic encapsulation layer 460”. Further, the portion extending further outward than the desired point in the inorganic encapsulation layer 460 is referred to as a shadow.

The bezel may increase due to the shadow phenomenon of the inorganic encapsulation layer 460. In other words, the shadow phenomenon of the inorganic encapsulation layer 460 may be a limiting factor in implementing the narrow bezel.

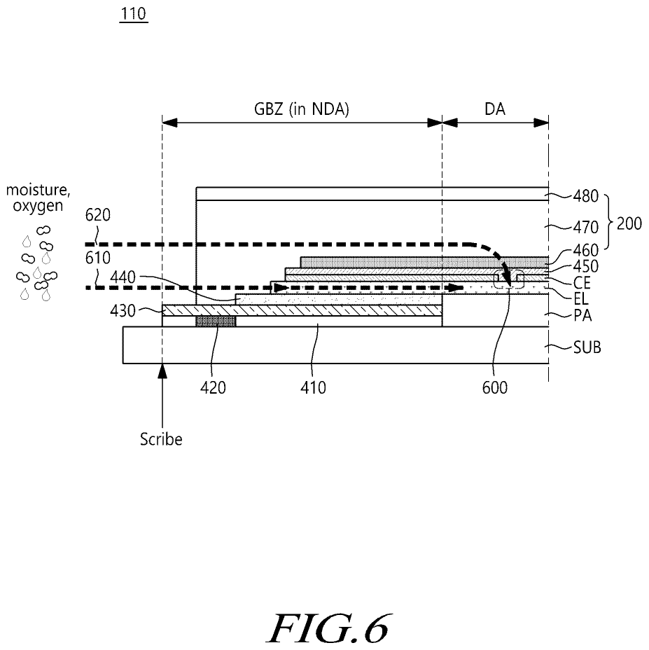

FIG. 6 is an example diagram illustrating an image abnormality of a display panel 110 according to one or more example embodiments of the present disclosure.

Referring to FIG. 6, when an external material (e.g., moisture, oxygen, etc.) is introduced into the display panel 110 and reaches a predetermined point of the intermediate layer EL or the common electrode CE, an image abnormality occurs.

Referring to FIG. 6, an external material (e.g., moisture, oxygen, etc.) present in the atmosphere may be introduced into the display panel 110 through the adhesive layer 470.

Referring to FIG. 6, the external material introduced into the display panel 110 may be introduced into the intermediate layer EL after reaching a point where the adhesive layer 470 and the intermediate layer EL contact each other. The external material introduced into the intermediate layer EL may reach the display area DA along a first moving path 610. The moving path of the external material is referred to as the first moving path 610.

The external material introduced into the intermediate layer EL along the first moving path 610 may oxidize the common electrode CE in contact with the intermediate layer EL. This phenomenon may be continuously spread to various points in the display area DA and perceived with the naked eye.

Referring to FIG. 6, the external material introduced into the display panel 110 may reach the defective portion 600 of the common electrode CE along the adhesive layer 470. The moving path of the external material is referred to as a second moving path 620.

The external material reaching the defective portion 600 of the common electrode CE along the second moving path 620 may oxidize the common electrode CE. This phenomenon may be continuously spread to various points in the display area DA and perceived with the naked eye.

The above-described image abnormality caused by the inflow and internal movement of the external material may occur during the manufacturing process of the display panel 110 or may occur even after the manufacture of the display panel 110 is completed.

Meanwhile, as the film formation on the substrate is repeated during the deposition process using plasma, sediment, which is a deposition material, may be unevenly accumulated on the upper surface, the side surface, or the mask of the chamber in addition to the substrate disposed in the chamber. When the sediment forms a film exceeding a certain thickness, the sediment may affect the flow or heat distribution of the deposition gas, thereby hindering the film formation rate or uniformity of the film formation. Further, foreign matter may be generated by the sediment and attached to the substrate, causing a defect in the film formation.

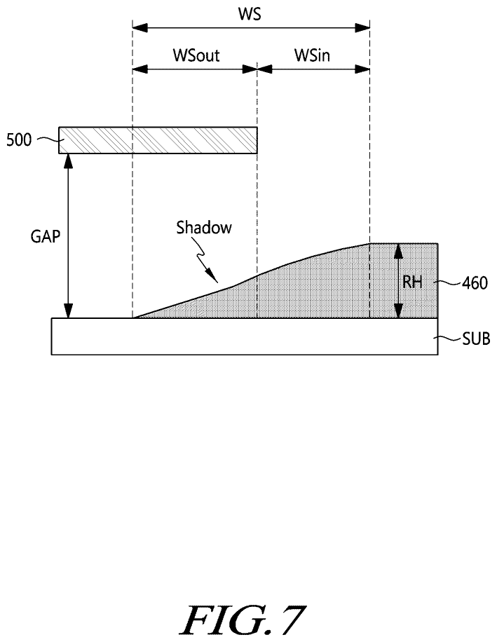

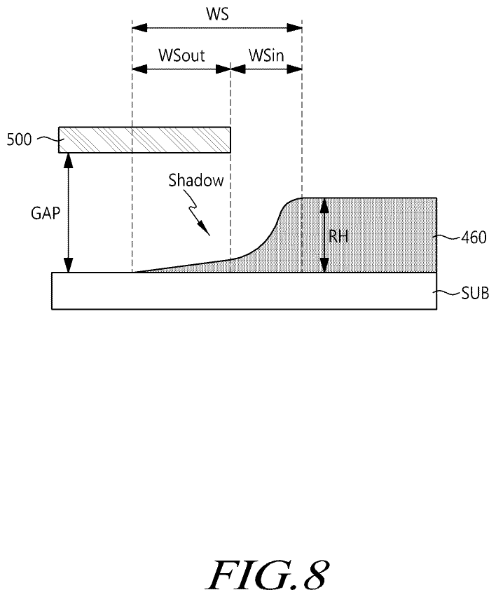

FIGS. 7 and 8 are example diagrams illustrating a shadow phenomenon of an inorganic encapsulation layer 460 according to the distance between a substrate SUB and a mask stick 500 in a display panel 110 according to one or more example embodiments of the present disclosure.

FIGS. 7 and 8 are example diagrams illustrating a change in the width WS of the shadow area of the inorganic encapsulation layer 460 formed on the non-display area NDA according to the gap GAP between the substrate SUB and the mask stick 500.

The shadow area may include an outer shadow area and an inner shadow area. The outer shadow area may be defined as an area in which the inorganic encapsulation layer 460 overlaps the mask stick 500 and is disposed under the mask stick 500. The inner shadow area may be defined as an area in which the inorganic encapsulation layer 460 is disposed between an end of the mask stick 500 and a point at which the inorganic encapsulation layer 460 has a reference height RH.

Referring to FIG. 7, if the deposition process of the inorganic encapsulation layer 460 is performed with a wide gap GAP set between the substrate SUB and the mask stick 500, when the inorganic encapsulation layer 460 is deposited by the reference height RH, it may be deposited to extend further outward than the desired point which corresponds to the reference height RH, due to the widened gap GAP between the mask stick 500 and the substrate SUB. In other words, the width WSout of the outer shadow area and the width WSin of the inner shadow area may increase, thereby increasing the overall width WS of the shadow area.

Referring to FIG. 8, if the deposition process of the inorganic encapsulation layer 460 is performed with a narrow gap GAP set between the substrate SUB and the mask stick 500, when the inorganic encapsulation layer 460 is deposited by the reference height RH, it may be deposited to extend closer to the desired point which corresponds to the reference height RH, due to the narrow gap GAP between the mask stick 500 and the substrate SUB. In other words, the width WSout of the outer shadow area and the width WSin of the inner shadow area may be reduced, and thus the overall width WS of the shadow area may be reduced.

For example, in order to deposit the inorganic encapsulation layer 460 by the reference height RH, when the gap GAP between the substrate SUB and the inorganic encapsulation layer 460 is set to a ratio of 1, 2/3, and 1/3, the width WS of the shadow area may be reduced to 100%, about 75%, and about 50%. In other words, it may be advantageous in implementing a narrow bezel to reduce the width WS of the shadow area of the inorganic encapsulation layer 460 by adjusting the gap GAP between the substrate SUB and the mask stick 500.

Meanwhile, since the deposition material is deposited on the mask stick 500 in the direction of the substrate SUB, the shadow phenomenon may be reduced not only by the gap GAP between the substrate SUB and the mask stick 500 but also by the thickness of the mask stick 500. In other words, if the thickness of the mask stick 500 is reduced, the gap GAP between the substrate SUB and the mask stick 500 may be reduced by the reduced thickness of the mask stick 500.

For example, in order to deposit the inorganic encapsulation layer 460 by the reference height RH, when the thickness of the mask stick 500 is set to a ratio of 100% and about 86%, the width WS of the shadow area may be reduced to 100% and about 78%. In other words, it may be advantageous in implementing a narrow bezel to reduce the width WS of the shadow area of the inorganic encapsulation layer 460 by adjusting the thickness of the mask stick 500.

It is possible to implement a narrow bezel of the display device by reducing the width WS of the shadow area of the inorganic encapsulation layer 460 by adjusting the thickness of the mask stick 500 and/or the gap GAP between the substrate SUB and the mask stick 500.

Hereinafter, a mask frame and a method of manufacturing the mask frame are described in more detail.

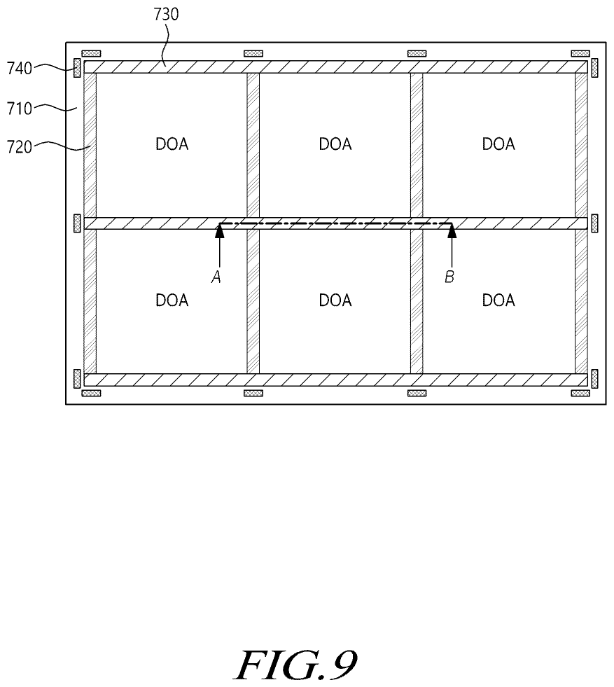

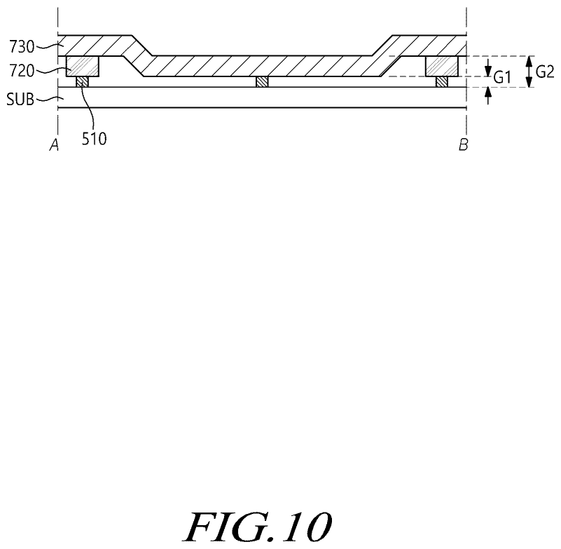

FIG. 9 is an example plan view illustrating a mask assembly according to one or more example embodiments of the present disclosure. FIG. 10 is an example cross-sectional view taken along line A-B of FIG. 9.

Referring to FIG. 9, a mask assembly according to one or more example embodiments of the present disclosure may include a mask frame 710 and a mask stick. The mask stick may include a first mask stick 720 and a second mask stick 730.

The first mask stick 720 and the second mask stick 730 may be disposed on the mask frame 710 to cross each other, thereby forming a plurality of deposition opening areas DOA.

The first mask stick 720 may be disposed on the mask frame 710 to be spaced apart in a first direction and extend in a second direction crossing the first direction. The first mask stick 720 may be coupled to the mask frame 710 by laser welding. A welding portion 740 may be formed at a point where the first mask stick 720 and the mask frame 710 are coupled.

The second mask stick 730 may be disposed on the mask frame 710 and the first mask stick 720 to be spaced apart in the second direction and extend in the first direction. The second mask stick 730 may be coupled to the mask frame 710 by laser welding. A welding portion 740 may be formed at a point (or each point) where the second mask stick 730 and the mask frame 710 are coupled.

Referring to FIG. 9, the welding portion 740 may be disposed along the mask frame 710.

Meanwhile, the first mask stick 720 and the second mask stick 730 may be disposed to cross each other, so that a step may occur between the first mask stick 720 and the second mask stick 730.

Referring to FIG. 10, at a point where the first mask stick 720 and the second mask stick 730 cross, a gap G2 between the substrate SUB and the second mask stick 730 disposed on the first mask stick 720 may correspond to a thickness obtained by adding the thickness of the first mask stick 720 and the thickness of the protrusion 510. On the other hand, between the points where the first mask stick 720 and the second mask stick 730 cross, the thickness G1 between the substrate SUB and the second mask stick 730 may correspond to the thickness of the protrusion 510.

In other words, a step may occur at the point where the first mask stick 720 and the second mask stick 730 cross each other and the point where the first mask stick 720 and the second mask stick 730 do not cross each other, causing a shadow in a wide range in the deposition opening areas DOA of the plurality of unit display panel during the deposition process.

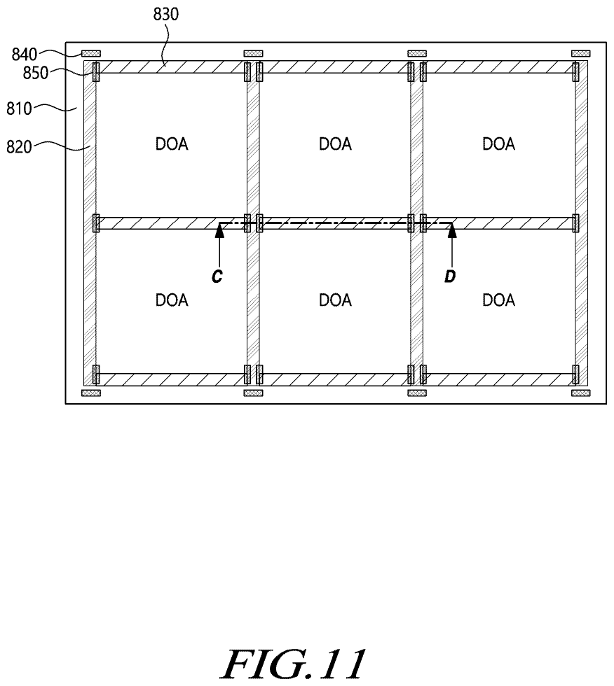

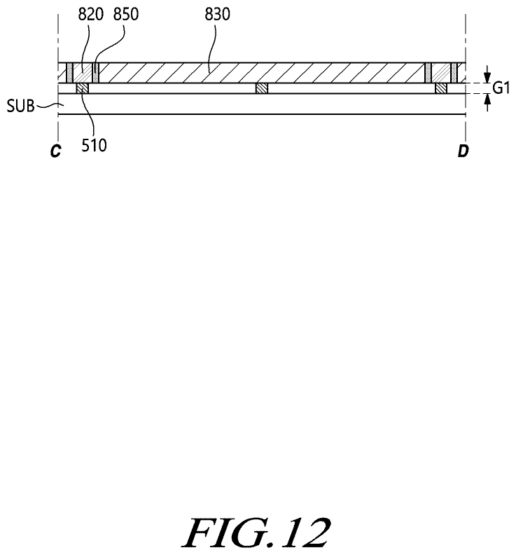

FIG. 11 is another example plan view illustrating a mask assembly according to one or more example embodiments of the present disclosure. FIG. 12 is an example cross-sectional view taken along line C-D of FIG. 11.

Referring to FIG. 11, a mask assembly according to one or more example embodiments of the present disclosure may include a mask frame 810 and a mask stick. The mask stick may include a first mask stick 820 and a second mask stick 830. The first mask stick 820 and the second mask stick 830 may have the same thickness.

The first mask stick 820 may be disposed on, or coupled to, the mask frame 810 and may be spaced apart in a first direction and extend in a second direction crossing the first direction. The first mask stick 820 may be spaced apart at the same interval in the first direction. The first mask stick 820 may be coupled to the mask frame 810 by laser welding. A first welding portion 840 may be formed at a point (or each point) where the first mask stick 820 and the mask frame 810 are coupled.

The second mask stick 830 may be spaced apart in the second direction and may be disposed to extend in the first direction. The second mask stick 830 may be spaced apart at the same interval in the second direction. The two opposite end surfaces of the second mask stick 830 may be coupled to side surfaces of the first mask stick 820, wherein the first mask stick 820 may be spaced apart from each other. The two opposite end surfaces of the second mask stick 830 and side surfaces of the first mask stick 820 may be coupled by laser welding. A second welding portion 850 may be formed at a point (or each point) where the first mask stick 820 and the second mask stick 830 are coupled.

As the two opposite end surfaces of the second mask stick 830 are coupled to the side surfaces of the first mask stick 820, a plurality of deposition opening areas DOA may be formed.

Referring to FIG. 11, a first welding portion 840 where the first mask stick 820 and the mask frame 810 are coupled by welding may be disposed on the mask frame 810 along the end of the first mask stick 820. A second welding portion 850 where the first mask stick 820 and the second mask stick 830 are coupled by welding may be disposed at two opposite ends of the second mask stick 830.

The side surfaces of the first mask stick 820 and two opposite end surfaces of the second mask stick 830 may be coupled by welding, and the first mask stick 820 and the second mask stick 830 may have the same thickness. Due to this structure, no step may occur between the first mask stick 820 and the second mask stick 830.

Referring to FIG. 12, the side surfaces of the first mask stick 820 and the two opposite end surfaces of the second mask stick 830 may be coupled to each other by the second welding portion 850.

Referring to FIG. 12, a protrusion 510 may be disposed between the mask stick and the substrate SUB. The protrusion 510 may be coupled to a lower portion of the first mask stick 820. The protrusion 510 may be coupled to a lower portion of the second mask stick 830. At least one protrusion 510 may be coupled to the mask stick.

The protrusion 510 may be coupled to the mask stick. The protrusion 510 may be coupled to a lower portion of the welding portion of the first mask stick 820 and the second mask stick 830. The protrusion 510 may be coupled to a lower portion of the welding portion with the first mask stick 820 and the second mask stick 830.

Referring to FIG. 12, the gap G1 between the substrate SUB and the mask stick including the first mask stick 820 and the second mask stick 830 may remain constant. In other words, the gap G1 between the substrate SUB and the mask stick may correspond to the thickness of the protrusion 510.

The gap G1 between the substrate SUB and the mask stick may be kept constant to prevent or reduce the occurrence of shadows in the deposition opening areas DOA of the plurality of unit display panels during the deposition process.

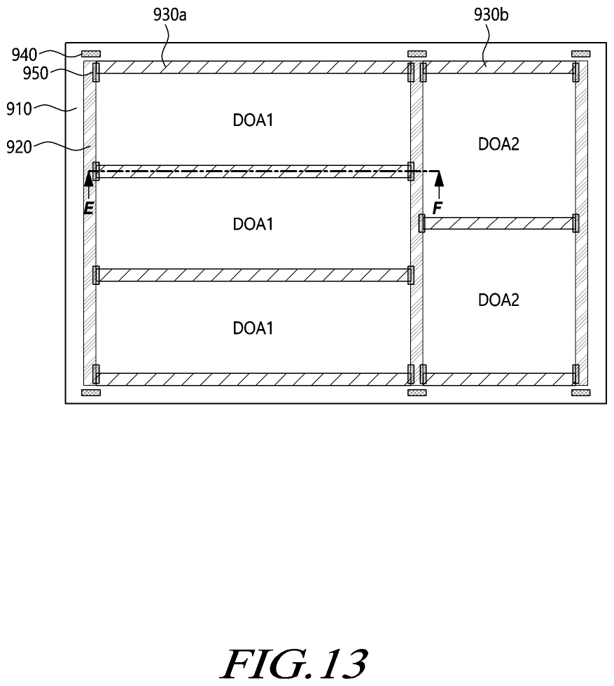

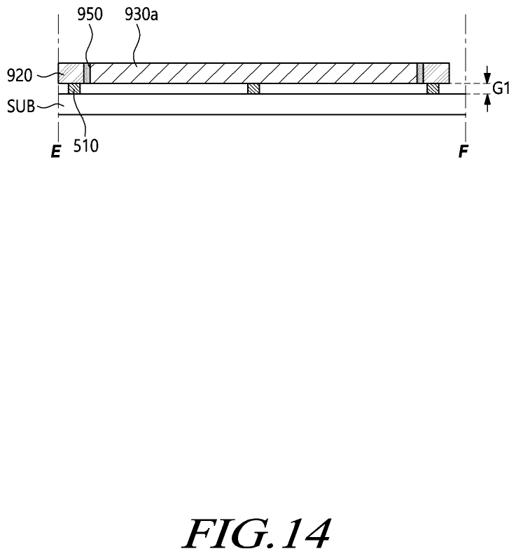

FIG. 13 is another example plan view illustrating a mask assembly according to one or more example embodiments of the present disclosure. FIG. 14 is an example cross-sectional view taken along line E-F of FIG. 13.

Referring to FIG. 13, a mask assembly according to one or more example embodiments of the present disclosure may include a mask frame 910 and a mask stick. The mask stick may include a first mask stick 920 and a second mask stick 930. The first mask stick 920 and the second mask stick 930 may have the same thickness. The second mask stick 930 may include a first stick bar 930a and a second stick bar 930b.

The first mask stick 920 may be disposed on the mask frame 910 and may be spaced apart in a first direction and extend in a second direction crossing the first direction. The first mask stick 920 may be spaced apart at a different interval in the first direction. The first mask stick 920 may be coupled to the mask frame 910 by laser welding. A first welding portion 940 may be formed at a point where the first mask stick 920 and the mask frame 910 are coupled.

The second mask stick 930 may include a first stick bar 930a and a second stick bar 930b spaced apart from each other in the first direction. The length of the first stick bar 930a and the length of the second stick bar 930b may be the same as each other. Further, the length of the first stick bar 930a and the length of the second stick bar 930b may be different from each other.

The first stick bar 930a may be spaced apart in the second direction. The second stick bar 930b may be spaced apart in the second direction. The spacing of the first stick bar 930a in the second direction and the spacing of the second stick bar 930b in the second direction may be the same. Further, the spacing of the first stick bar 930a in the second direction may be different from the spacing of the second stick bar 930b in the second direction.

The two opposite end surfaces of the first stick bar 930a may be coupled to side surfaces of the first mask stick 920 and wherein the first mask stick 920 may be spaced apart from each other. The two opposite end surfaces of the first stick bar 930a and side surfaces of the first mask stick 920 may be coupled by laser welding. A second welding portion 950 may be formed at a point where the first stick bar 930a and the first mask stick 920 are coupled.

The two opposite end surfaces of the second stick bar 930b may be coupled to side surfaces of the first mask stick 920 and wherein the first mask stick 920 may be spaced apart from each other. The two opposite end surfaces of the second stick bar 930b and side surfaces of the first mask stick 920 may be coupled by laser welding. A second welding portion 950 may be formed at a point where the second stick bar 930b and the first mask stick 920 are coupled.

As two opposite end surfaces of the first stick bar 930a are coupled to the side surfaces of the first mask stick 920, a plurality of first deposition opening areas DOA1 may be formed, and as two opposite end surfaces of the second stick bar 930b are coupled to the side surfaces of the first mask stick 920, a plurality of second deposition opening areas DOA2 may be formed. The size of the first deposition opening area DOA1 and the size of the second deposition opening area DOA2 may be different.

Referring to FIG. 13, a first welding portion 940 where the first mask stick 920 and the mask frame 910 are coupled by welding may be disposed on the mask frame 910 along the end of the first mask stick 920. A second welding portion 950 where the first mask stick 920 and the first stick bar 930a are coupled by welding may be disposed at two opposite ends of the first stick bar 930a. A second welding portion 950 where the first mask stick 920 and the second stick bar 930b are coupled by welding may be disposed at two opposite ends of the second stick bar 930b.

The side surfaces of the first mask stick 920, two opposite end surfaces of the first stick bar 930a, and two opposite end surfaces of the second stick bar 930b may be coupled by welding, and the first mask stick 920, the first stick bar 930a, and the second stick bar 930b may have the same thickness. Due to this structure, no step may occur between the first mask stick 920 and the first stick bar 930a and the second stick bar 930b.

Referring to FIG. 14, the side surfaces of the first mask stick 920 and two opposite end surfaces of the first stick bar 930a may be coupled to each other by the second welding portion 950. The gap G1 between the substrate SUB and the mask stick including the first mask stick 920 and the first stick bar 930a may remain constant. In other words, the gap G1 between the substrate SUB and the mask stick may correspond to the thickness of the protrusion 510.

The gap G1 between the substrate SUB and the mask stick may be kept constant to prevent or reduce the occurrence of shadows in the deposition opening areas DOA1 and DOA2 of the plurality of unit display panels during the deposition process.

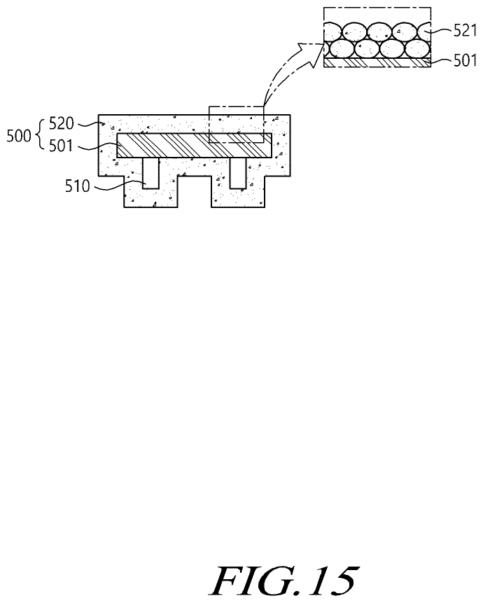

FIG. 15 is an example cross-sectional view illustrating a mask stick 500 having a coating layer 520 according to one or more example embodiments of the present disclosure.

Referring to FIG. 15, the mask stick 500 may include a mask stick body 501 and a coating layer 520 coated on the mask stick body 501.

During the deposition process using plasma, sediments caused by plasma may accumulate on the mask stick. When foreign matter is generated by such sediments and attached to the substrate, it may cause a defect in the film formation. The mask stick may be coated with a plasma-resistant material to prevent plasma-induced sediment from accumulating on the mask stick.

When the thickness of the coating layer is thick, the gap between the mask stick and the substrate may increase, and thus the shadow area may increase. For example, when the coating layer 520 is formed on the mask stick body 501 using the aluminum oxide (Al₂O₃) particles 521 as a coating material, the thickness of the coating layer 520 is thicker than the thickness of the mask stick body 501, and thus the gap between the mask stick and the substrate may increase, thereby increasing the shadow area. The mask stick 500 may couple the protrusion 510 to a lower portion of the mask stick 500 to maintain the gap with the substrate. The distance between the substrate and the upper portion of the mask stick 500 may be defined as a sum of the thickness of the mask stick body 501, the thickness of the protrusion 510, and the thickness of the coating layer 520. When the thickness of the mask stick body 501 and the thickness of the protrusion 510 are constant, the distance between the substrate and the upper portion of the mask stick 500 may vary depending on the thickness of the coating layer 520. In other words, when the thickness of the coating layer 520 is large, the distance between the substrate and the upper portion of the mask stick 500 may increase, and when the thickness of the coating layer 520 is small, the distance between the substrate and the upper portion of the mask stick 500 may decrease.

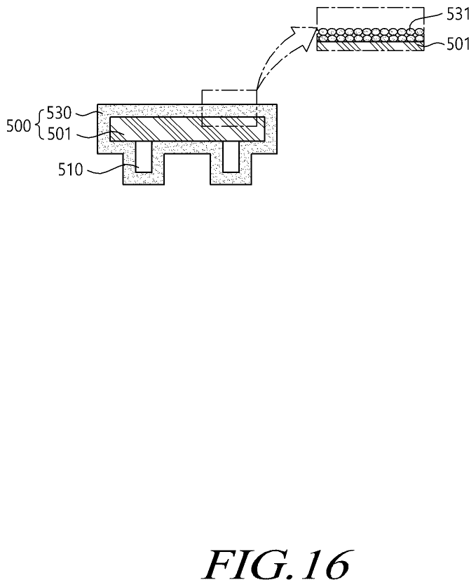

FIG. 16 is another example cross-sectional view illustrating a mask stick 500 having a coating layer 530 according to one or more example embodiments of the present disclosure.

Referring to FIG. 16, the mask stick 500 may include a mask stick body 501 and a coating layer 530 coated on the mask stick body 501.

The thickness of the coating layer 530 may be ¼ to ½ of the thickness of the mask stick body 501. When the thickness of the coating layer 530 is less than ¼ of the thickness of the mask stick body 501, plasma resistance may be reduced. When the thickness of the coating layer 530 exceeds ½ of the thickness of the mask stick body 501, the thickness of the mask stick 500 may increase, and thus the effect of reducing the shadow area may be reduced.

The coating layer 530 may include particles 531. The particle 531 may have a particle diameter of 2 μm or less, but greater than 0 μm. The particles 531 may include at least one selected from Y₂O₃, YF₃, YOF, YSZ, YAG, Cr₂O₃, TiO₂, and ZrO₂. In one or more examples, the particles 531 may include at least one selected from the group consisting of Y₂O₃, YF₃, YOF, YSZ, YAG, Cr₂O₃, TiO₂, and ZrO₂.

The mask stick 500 may include at least one protrusion 510 on one surface of the mask stick body 501. The coating layer 530 may be coated to surround the mask stick body 501 and the protrusion 510.

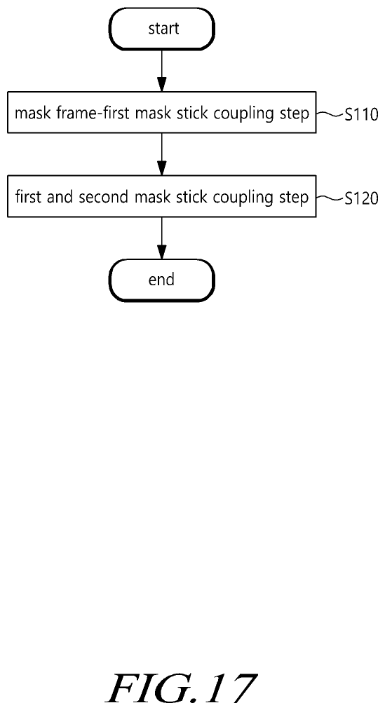

FIG. 17 is an example process flowchart illustrating a method for manufacturing a mask assembly according to one or more example embodiments of the present disclosure.

Referring to FIG. 17, a method of manufacturing a mask assembly according to one or more example embodiments of the present disclosure may include a mask frame-first mask stick coupling step S110 and a first and second mask stick coupling step S120.

The first mask stick and the second mask stick may include a mask stick body and a coating layer coated on the mask stick body.

The coating layer may include particles of (or particles having a diameter of) 2 μm or less, but greater than 0 μm. The particles may include at least one selected from Y₂O₃, YF₃, YOF, YSZ, YAG, Cr₂O₃, TiO₂, and ZrO₂. In one or more examples, the particles may include at least one selected from the group consisting of Y₂O₃, YF₃, YOF, YSZ, YAG, Cr₂O₃, TiO₂, and ZrO₂.

The first mask stick and the second mask stick may include at least one protrusion on one surface of the mask stick body. The coating layer may be coated on the mask stick body and the protrusion.

The mask frame and the first mask stick coupling step S110 may include coupling the first mask stick to the mask frame by laser welding.

First, a mask frame where the first mask stick is to be coupled may be prepared. Next, the first mask stick may be loaded and prepared. Next, the loaded first mask stick may be tensioned and aligned on the mask frame. The first mask stick may be spaced apart and aligned in the first direction on the mask frame. Next, the first mask stick may be coupled to the mask frame by laser welding. On the mask frame, the portion where the first mask stick protrudes outward may be cut off.

The first and second mask stick coupling step S120 may include coupling side surfaces of the first mask sticks disposed to be spaced apart with two opposite end surfaces of the second mask stick by laser welding.

First, a second mask stick may be prepared by cutting to correspond to the spacing from the first mask stick. Next, the cut second mask stick may be aligned in the second direction crossing the first direction and disposed on the side surface of the first mask stick. A mask assembly may be manufactured by coupling two opposite end surfaces of the aligned second mask stick and the side surfaces of the first mask stick by laser welding.

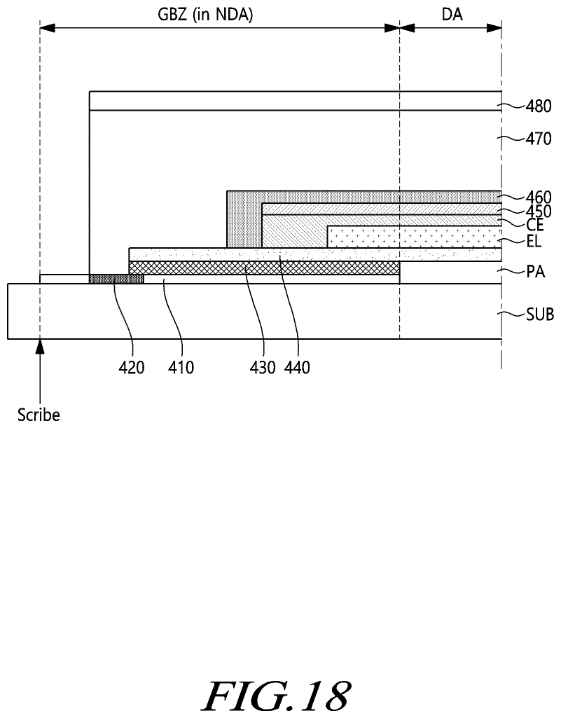

FIG. 18 is an example cross-sectional view of a display panel 110 according to one or more example embodiments of the present disclosure. The following description focuses primarily on differences from the cross-sectional view of FIG. 4 while omitting the description of the same content as that of the cross-sectional view of FIG. 4.

Referring to FIG. 18, in the display panel 110 according to one or more example embodiments of the present disclosure, the inorganic encapsulation layer 460 deposited according to the deposition method described with reference to FIG. 5 extends to an outer area of the common electrode CE. A portion (i.e., a portion of the inorganic encapsulation layer 460) extending from the inorganic encapsulation layer 460 to the outer area of the common electrode CE is referred to as a “shadow”.

Referring to FIG. 18, a display panel 110 according to one or more example embodiments of the present disclosure may include a substrate SUB, a display area DA where a plurality of subpixels SP are disposed, a non-display area outside the display area DA, a circuit unit 410 disposed on the substrate SUB and disposed in the non-display area, an overcoat layer 430 disposed on the circuit unit 410, a bank 440 extending from the display area DA to the non-display area and disposed on the overcoat layer 430, an intermediate layer EL extending from the display area DA to the non-display area and disposed on the bank 440, a common electrode CE extending from the display area DA to the non-display area and disposed on the intermediate layer EL, and an inorganic encapsulation layer 460 extending from the display area DA to the non-display area and disposed to cover an upper portion and a side surface of the common electrode CE.

Referring to FIG. 18, the intermediate layer EL may be disposed to extend to a partial area of an upper portion of the bank 440 disposed in the non-display area NDA. The common electrode CE may be disposed to cover the upper and side surfaces of the intermediate layer EL disposed in the non-display area NDA. The inorganic encapsulation layer 460 may be disposed to cover the upper and side surfaces of the common electrode CE disposed in the non-display area NDA.

Referring to FIG. 18, an end of the inorganic encapsulation layer 460 may contact the bank 440 disposed in the non-display area NDA. The end of the inorganic encapsulation layer 460 may be disposed to contact a portion of the upper surface of the bank 440 disposed in the non-display area NDA. By applying the mask assembly according to one or more example embodiments of the present disclosure, a shadow of the inorganic encapsulation layer 460 may be reduced. Because the shadow of the inorganic encapsulation layer 460 is reduced, the inorganic encapsulation layer 460 may be disposed to surround the common electrode CE without being disposed to extend to the end of the bank 440. In other words, the inorganic encapsulation layer 460 may be disposed to extend to inside an end of the bank 440 disposed in the non-display area NDA. It may be advantageous to implement a narrow bezel by minimizing an area where the inorganic encapsulation layer 460 is disposed outside the display area DA.

Referring to FIG. 18, a capping layer 450 disposed on the common electrode CE may be further included. The inorganic encapsulation layer 460 may be disposed to cover an upper portion of the capping layer 450 and side surfaces of the capping layer 450 and the common electrode CE.

The circuit 410 may include a gate-in-panel circuit GIPC for outputting a scan signal to the plurality of subpixels SP, a plurality of gate clock lines GCLKL disposed between an outermost area of the non-display area NDA and the gate-in-panel circuit GIPC, a first gate voltage line GVDDL disposed between the plurality of gate clock lines GCLKL and the gate-in-panel circuit GIPC, and a second gate voltage line GVSSL disposed between the gate-in-panel circuit GIPC and the display area DA.

Referring to FIG. 18, a ground line 420 may be disposed further outside than the circuit unit 410.

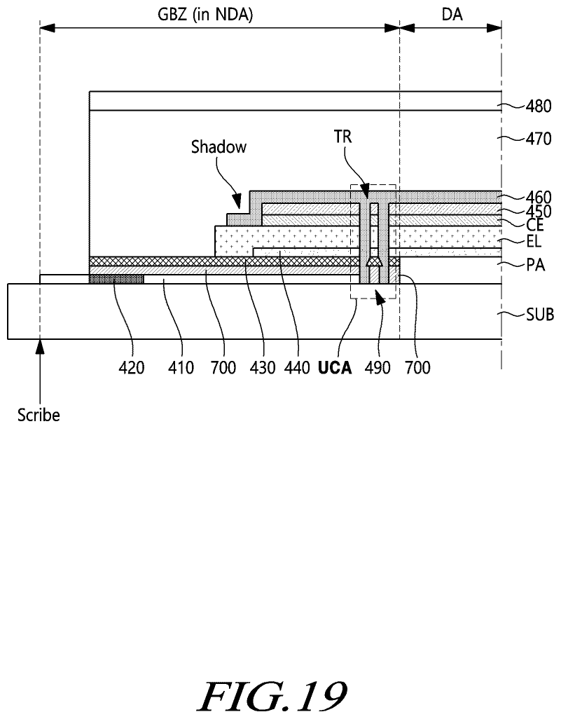

FIG. 19 is another example cross-sectional view of a display panel 110 according to one or more example embodiments of the present disclosure. The following description focuses primarily on differences from the cross-sectional view of FIGS. 4 and 18 while omitting the description of the same content as that of the cross-sectional view of FIGS. 4 and 18.

Referring to FIG. 19, the display panel 110 according to one or more example embodiments of the present disclosure may include an undercut structural area UCA to prevent a side effect caused by a shadow of the inorganic encapsulation layer 460 and to prevent an image abnormality.

Side effects due to the shadow of the inorganic encapsulation layer 460 may include bezel extension due to the shadow of the inorganic encapsulation layer 460 and moisture permeation diffusion due to cracks of the shadow of the inorganic encapsulation layer 460. Here, in one or more aspects, the moisture permeable diffusion due to the crack of the shadow of the inorganic encapsulation layer 460 may mean that the moisture penetrated due to the crack of the shadow of the inorganic encapsulation layer 460 is deeply diffused to another area.

Referring to FIG. 19, the undercut structural area UCA is an area where the protrusion 490 is formed inside the trench TR. Here, the protrusion 490 may also be referred to as a tip.

The trench TR may be positioned between the circuit unit 410 and the display area DA. The trench TR may be an area where the overcoat layer 430, the bank 440, the intermediate layer EL, and the common electrode CE have been removed (or are absent).

Due to the undercut structural area UCA, diffusion of an external material (e.g., moisture, oxygen, etc.) introduced from the non-display area NDA to the common electrode CE or from the display area DA to the common electrode CE may be prevented.

Referring to FIG. 19, the intermediate layer EL may be disposed to extend to the upper and side surfaces of the bank 440 disposed in the non-display area NDA. The inorganic encapsulation layer 460 may be disposed to extend to inside the end of the intermediate layer EL disposed in the non-display area NDA. In other words, in one or more aspects, the inorganic encapsulation layer 460 may be disposed on the upper surface of the intermediate layer EL in the non-display area NDA, and may not be disposed on the side surfaces (or the outer side surfaces) of the intermediate layer EL. The inorganic encapsulation layer 460 may fill the inside the trench TR.

Referring to FIG. 19, the display panel 110 according to one or more example embodiments of the present disclosure may further include a capping layer 450 disposed on the common electrode CE. The inorganic encapsulation layer 460 may be disposed to cover an upper portion of the capping layer 450, side surfaces of the capping layer 450 and the common electrode CE, and an upper portion of the intermediate layer EL.

Referring to FIG. 19, the display panel 110 according to one or more example embodiments of the present disclosure may further include a protrusion 490 protruding from the substrate SUB and positioned between the circuit unit 410 and the display area DA. The protrusion 490 may be disposed inside the trench TR.

In one or more other examples, the protrusion 490 may include a protection layer 700 pattern, an overcoat layer 430 pattern, a bank 440 pattern, an intermediate layer EL pattern and a common electrode CE pattern. The overcoat layer 430 pattern may be positioned on the protection layer 700 pattern. A rear surface of the overcoat layer 430 pattern facing the substrate SUB may have a larger area or region than the upper surface of the protection layer 700 pattern. The bank 440 pattern may be positioned on the overcoat layer 430 pattern. The intermediate layer EL pattern may be positioned on the bank 440 pattern. The common electrode CE pattern may be positioned on the intermediate layer EL pattern. Meanwhile, the bank 440 pattern is disposed on the overcoat layer 430 pattern, but embodiments of the present disclosure are not limited thereto. In another example, the bank 440 pattern is not disposed on the overcoat layer 430 pattern.

The protrusion 490 and the inorganic encapsulation layer 460 are not broken around the protrusion 490. In other words, the inorganic encapsulation layer 460 may be disposed on the protrusion 490 and may be seamlessly disposed in an outer area and an inner area of the trench TR.

Referring to FIG. 19, a protrusion 490 may be disposed inside a trench TR. In one or more example, in the process of forming the protrusion 490, the trench TR may be formed. Other examples, in the process of forming the trench TR, the protrusion 490 may be formed. Other examples, the protrusion 490 and the trench TR may be formed simultaneously. For example, the trench (TR) may be formed by removing a part of the material layer. The material layer may include an overcoat layer 430, an intermediate layer EL, a bank 440, and a common electrode CE. At this time, inside the trench (TR), the protrusion (490) may be formed by the remaining overcoat layer (430) pattern, bank (440) pattern, intermediate layer (EL) pattern, and common electrode (CE) pattern.

In one or more aspects, an element may include or may be one or more elements. In one or more aspects, an element may include or may be one or more portions of the element. In one or more aspects, a first mask stick may include one or more first mask sticks, and a second mask stick may include one or more second mask sticks. In one or more aspects, a first mask stick may include or may be one or more portions of the first mask stick, and a second mask stick may include or may be one or more portions of the second mask stick.

One or more example embodiments of the present disclosure described above are briefly described below.

A mask assembly according to one or more example embodiments of the present disclosure may comprise a mask frame and a mask stick coupled to the mask frame and including a plurality of first mask sticks spaced apart in a first direction and extending in a second direction crossing the first direction and a plurality of second mask sticks spaced apart in the second direction and extending in the first direction. Two opposite end surfaces of the second mask stick may be respectively coupled to corresponding side surfaces of the first mask sticks that may be spaced apart from each other.

According to the mask assembly according to one or more example embodiments of the present disclosure, the first mask stick or the second mask stick may include a mask stick body and a coating layer coated on the mask stick body.

According to the mask assembly according to one or more example embodiments of the present disclosure, a thickness of the coating layer may be ¼ to ½ of a thickness of the mask stick body.

According to the mask assembly according to one or more example embodiments of the present disclosure, the coating layer may include particles. The particle may have a particle diameter of 2 μm or less, but greater than 0 μm. The particles may include at least one material selected from Y₂O₃, YF₃, YOF, YSZ, YAG, Cr₂O₃, TiO₂, and ZrO₂.

According to the mask assembly according to one or more example embodiments of the present disclosure, the mask stick may include at least one protrusion on one surface of the mask stick body. The coating layer may be coated on the mask stick body and the at least one protrusion.

According to the mask assembly according to one or more example embodiments of the present disclosure, a thickness of the first mask stick and a thickness of the second mask stick may be identical to each other.

According to the mask assembly according to one or more example embodiments of the present disclosure, an entire lower surface of the second mask stick may be planar without a step.

According to the mask assembly according to one or more example embodiments of the present disclosure, the two opposite end surfaces of the second mask stick may be respectively coupled to the corresponding side surfaces of the first mask sticks that are spaced apart from each other by welding portions.

According to the mask assembly according to one or more example embodiments of the present disclosure, an upper surface of the second mask stick adjacent to one of the welding portions and an upper surface of the first mask stick adjacent to the one of the welding portions may be on a same level, and a lower surface of the second mask stick adjacent to the one of the welding portions and a lower surface of the first mask stick adjacent to the one of the welding portions may be on a same level.

According to the mask assembly according to one or more example embodiments of the present disclosure, the second mask stick may include a first stick bar and a second stick bar spaced apart from each other in the first direction. A length of the first stick bar and a length of the second stick bar may be identical to each other. A spacing of the respective first stick bars of the plurality of second mask sticks in the second direction and a spacing of the respective second stick bars of the plurality of second mask sticks in the second direction may be identical to each other.

According to the mask assembly according to one or more example embodiments of the present disclosure, the second mask stick may include a first stick bar and a second stick bar spaced apart from each other in the first direction. A length of the first stick bar and a length of the second stick bars of the plurality of second mask sticks may be different from each other. A spacing of the respective first stick bar in the second direction and a spacing of the respective second stick bars of the plurality of second mask sticks in the second direction may be different from each other

A method for manufacturing a mask assembly according to one or more example embodiments of the present disclosure may comprise providing a mask frame, coupling the mask frame to a first mask stick, wherein a plurality of the first mask sticks are spaced apart in a first direction, and coupling the first mask stick to a second mask stick, wherein a plurality of the second mask sticks are spaced apart in a second direction crossing the first direction, wherein two opposite end surfaces of the second mask stick are respectively welded to corresponding side surfaces of the first mask sticks that are spaced apart from each other.

According to the method for manufacturing the mask assembly according to one or more example embodiments of the present disclosure, coupling the mask frame to the first mask stick may include loading the first mask stick, stretching and aligning the first mask stick on the mask frame, and welding the first mask stick to the mask frame.

According to the method for manufacturing the mask assembly according to one or more example embodiments of the present disclosure, coupling the first mask stick to the second mask stick may include cutting the second mask stick to correspond to a spacing of the first mask sticks that are spaced apart from each other and respectively coupling the two opposite end surfaces of the second mask stick to the corresponding side surfaces of the first mask sticks that are spaced apart from each other by laser welding.

According to the method for manufacturing the mask assembly according to one or more example embodiments of the present disclosure, the first mask stick and the second mask stick may each include a mask stick body and a coating layer coated on the mask stick body.

According to the method for manufacturing the mask assembly according to one or more example embodiments of the present disclosure, the coating layer may include particles. The particle may have a particle diameter of 2 μm or less, but greater than 0 μm. The particles may include at least one material selected from Y₂O₃, YF₃, YOF, YSZ, YAG, Cr₂O₃, TiO₂, and ZrO₂.

According to the method for manufacturing the mask assembly according to one or more example embodiments of the present disclosure, the first mask stick and the second mask stick may each further include at least one protrusion on one surface of the mask stick body. The coating layer may be coated on the mask stick body and the at least one protrusion.

A display device according to one or more example embodiments of the present disclosure may comprise a substrate, a display area where a plurality of subpixels are disposed, a non-display area outside the display area, a circuit unit disposed on the substrate and disposed in the non-display area, an overcoat layer disposed on the circuit unit, a bank extending from the display area to the non-display area and disposed on the overcoat layer, an intermediate layer extending from the display area to the non-display area and disposed on the bank, a common electrode extending from the display area to the non-display area and disposed on the intermediate layer, and an inorganic encapsulation layer extending from the display area to the non-display area and disposed to cover an upper portion and a side surface of the common electrode.

According to the display device according to one or more example embodiments of the present disclosure, the intermediate layer may be disposed to extend to a partial area of an upper portion of the bank disposed in the non-display area. The common electrode may be disposed to cover an upper portion and a side surface of the intermediate layer disposed in the non-display area. The inorganic encapsulation layer may be disposed to cover the upper portion and the side surface of the common electrode disposed in the non-display area.

According to the display device according to one or more example embodiments of the present disclosure, an end of the inorganic encapsulation layer may contact the bank disposed in a non-display area.

The display device according to one or more example embodiments of the present disclosure may further comprise a capping layer disposed on the common electrode. The inorganic encapsulation layer may be disposed to cover an upper portion of the capping layer, a side surface of the capping layer, and the side surface of the common electrode.

According to the display device according to one or more example embodiments of the present disclosure, the inorganic encapsulation layer may be disposed to extend to inside an end of the intermediate layer disposed in the non-display area.

The display device according to one or more example embodiments of the present disclosure may further comprise a trench positioned between the circuit unit and the display area. An inside of the trench may be filled with the inorganic encapsulation layer.

According to the display device according to one or more example embodiments of the present disclosure, the trench may be an area where the overcoat layer, the bank, the intermediate layer, and the common electrode are removed (or are absent).

The display device according to one or more example embodiments of the present disclosure may further comprise a capping layer disposed on the common electrode. The inorganic encapsulation layer may be disposed to cover an upper portion of the capping layer, a side surface of the capping layer, the side surface of the common electrode, and an upper portion of the intermediate layer.

The display device according to one or more example embodiments of the present disclosure may further comprise a protrusion disposed inside the trench. The protrusion may include a protective layer pattern, an overcoat layer pattern positioned on the protective layer pattern and having a rear surface having an area larger than an upper surface of the protective layer pattern, a bank pattern on the overcoat layer pattern, an intermediate layer pattern on the bank pattern, and a common electrode pattern on the intermediate layer pattern.

According to the display device according to one or more example embodiments of the present disclosure, the circuit unit may include a gate-in-panel circuit for outputting a scan signal to the plurality of subpixels, a plurality of gate clock lines disposed between an outermost area of the non-display area and the gate-in-panel circuit, a first gate voltage line disposed between the plurality of gate clock lines and the gate-in-panel circuit, and a second gate voltage line disposed between the gate-in-panel circuit and the display area.

According to the display device according to one or more example embodiments of the present disclosure, the inorganic encapsulation layer may be disposed to extend to inside an end of the bank disposed in the non-display area.

According to the above-described one or more example embodiments of the present disclosure, there may be provided a mask assembly which allows a display device to have a narrow bezel and a highly reliable structure, a method for manufacturing the mask assembly, and a display device.

According to one or more example embodiments of the present disclosure, there may be provided a mask assembly having a structure advantageous in implementing a narrow bezel in a display device, a method for manufacturing the mask assembly, and a display device.

According to one or more example embodiments of the present disclosure, there may be provided a mask assembly having a structure capable of preventing penetration of external materials, such as moisture or oxygen, in a display device, a method for manufacturing the mask assembly, and a display device.

According to one or more example embodiments of the present disclosure, there may be provided a mask assembly having a structure capable of preventing generation of particles due to plasma, a method for manufacturing the mask assembly, and a display device.

According to one or more example embodiments of the present disclosure, there may be provided a mask assembly having a structure capable of blocking diffusion of external materials introduced into a display device and/or to a display area, a method for manufacturing the mask assembly, and a display device.

According to one or more example embodiments of the present disclosure, there may be provided a mask assembly which allows for a lightweight display device by having an extremely narrow bezel structure, a method for manufacturing the mask assembly, and a display device.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure. Thus, it is intended that the present disclosure covers the modifications and variations of this disclosure that come within the scope of the claims and their equivalents.

What is claimed:

1. A mask assembly, comprising:
a mask frame; and
a mask stick coupled to the mask frame and including a plurality of first mask sticks spaced apart in a first direction and extending in a second direction crossing the first direction and a plurality of second mask sticks spaced apart in the second direction and extending in the first direction,
wherein:
two opposite end surfaces of the second mask stick are respectively coupled to corresponding side surfaces of the first mask sticks that are spaced apart from each other.

2. The mask assembly of claim 1, wherein the first mask stick or the second mask stick includes a mask stick body and a coating layer coated on the mask stick body.

3. The mask assembly of claim 2, wherein a thickness of the coating layer is ¼ to ½ of a thickness of the mask stick body.

4. The mask assembly of claim 2, wherein the coating layer includes particles having a diameter of 2 μm or less, but greater than 0 μm, and
wherein the particles include at least one material selected from Y₂O₃, YF₃, YOF, YSZ, YAG, Cr₂O₃, TiO₂, and ZrO₂.

5. The mask assembly of claim 2, wherein the mask stick includes at least one protrusion on one surface of the mask stick body, and
wherein the coating layer is coated on the mask stick body and the at least one protrusion.

6. The mask assembly of claim 1, wherein a thickness of the first mask stick and a thickness of the second mask stick are identical to each other, and
wherein an entire lower surface of the second mask stick is planar without a step.

7. The mask assembly of claim 1, wherein the two opposite end surfaces of the second mask stick are respectively coupled to the corresponding side surfaces of the first mask sticks that are spaced apart from each other by welding portions,
wherein an upper surface of the second mask stick adjacent to one of the welding portions and an upper surface of the first mask stick adjacent to the one of the welding portions are on a same level, and
wherein a lower surface of the second mask stick adjacent to the one of the welding portions and a lower surface of the first mask stick adjacent to the one of the welding portions are on a same level.

8. The mask assembly of claim 1, wherein the second mask stick includes a first stick bar and a second stick bar spaced apart from each other in the first direction,
wherein a length of the first stick bar and a length of the second stick bar are identical to each other, and
wherein a spacing of the respective first stick bars of the plurality of second mask sticks in the second direction and a spacing of the respective second stick bars of the plurality of second mask sticks in the second direction are identical to each other.

9. The mask assembly of claim 1, wherein the second mask stick includes a first stick bar and a second stick bar spaced apart from each other in the first direction,
wherein a length of the first stick bar and a length of the second stick bar are different from each other, and
wherein a spacing of the respective first stick bars of the plurality of second mask sticks in the second direction and a spacing of the respective second stick bars of the plurality of second mask sticks in the second direction are different from each other.

10. A method for manufacturing a mask assembly, comprising:
providing a mask frame;
coupling the mask frame to a first mask stick, wherein a plurality of the first mask sticks are spaced apart in a first direction; and
coupling the first mask stick to a second mask stick, wherein a plurality of the second mask sticks are spaced apart in a second direction crossing the first direction,
wherein:
two opposite end surfaces of the second mask stick are respectively welded to corresponding side surfaces of the first mask sticks that are spaced apart from each other.

11. The method of claim 10, wherein coupling the mask frame to the first mask stick includes:
loading the first mask stick;
stretching and aligning the first mask stick on the mask frame; and
welding the first mask stick to the mask frame.

12. The method of claim 10, wherein coupling the first mask stick to the second mask stick includes:
cutting the second mask stick to correspond to a spacing of the first mask sticks that are spaced apart from each other; and
coupling the two opposite end surfaces of the second mask stick respectively to the corresponding side surfaces of the first mask sticks that are spaced apart from each other by laser welding.

13. The method of claim 10, wherein the first mask stick and the second mask stick each include a mask stick body and a coating layer coated on the mask stick body.

14. The method of claim 13, wherein the first mask stick and the second mask stick each further include at least one protrusion on one surface of the mask stick body, and
wherein the coating layer is coated on the mask stick body and the at least one protrusion.

15. A display device, comprising:
a substrate;
a display area where a plurality of subpixels are disposed;
a non-display area outside the display area;
a circuit unit disposed on the substrate and disposed in the non-display area;
an overcoat layer disposed on the circuit unit;
a bank extending from the display area to the non-display area and disposed on the overcoat layer;
an intermediate layer extending from the display area to the non-display area and disposed on the bank;
a common electrode extending from the display area to the non-display area and disposed on the intermediate layer; and
an inorganic encapsulation layer extending from the display area to the non-display area and disposed to cover an upper portion and a side surface of the common electrode.

16. The display device of claim 15, wherein the intermediate layer is disposed to extend to a partial area of an upper portion of the bank disposed in the non-display area,
wherein the common electrode is disposed to cover an upper portion and a side surface of the intermediate layer disposed in the non-display area, and
wherein the inorganic encapsulation layer is disposed to cover the upper portion and the side surface of the common electrode disposed in the non-display area.

17. The display device of claim 15, wherein the inorganic encapsulation layer is disposed to extend to inside an end of the intermediate layer disposed in the non-display area.

18. The display device of claim 15, further comprising a trench positioned between the circuit unit and the display area,
wherein an inside of the trench is filled with the inorganic encapsulation layer.

19. The display device of claim 18, further comprising a protrusion disposed inside the trench, wherein the protrusion includes:
a protective layer pattern;
an overcoat layer pattern positioned on the protective layer pattern and having a rear surface having an area larger than an upper surface of the protective layer pattern;
a bank pattern on the overcoat layer pattern;
an intermediate layer pattern on the bank pattern; and
a common electrode pattern on the intermediate layer pattern.

20. The display device of claim 15, wherein the circuit unit includes:
a gate-in-panel circuit for outputting a scan signal to the plurality of subpixels;
a plurality of gate clock lines disposed between an outermost area of the non-display area and the gate-in-panel circuit;
a first gate voltage line disposed between the plurality of gate clock lines and the gate-in-panel circuit; and
a second gat voltage line disposed between the gate-in-panel circuit and the display area.
